(19) United States
(12) Patent Application Publication
(10) Pub. No.: US 2026/0250826 A1
(43) Pub. Date: Aug. 27, 2026

(54) DEPOSITION MASK, DISPLAY DEVICE MANUFACTURED USING THE SAME AND ELECTRONIC DEVICE INCLUDING THE DISPLAY DEVICE

(71) Applicant: Samsung Display Co., LTD., Yongin-si (KR)

(72) Inventors: Jung Sun PARK, Yongin-si (KR); A Reum LEE, Yongin-si (KR); Joon Gu LEE, Yongin-si (KR)

(21) Appl. No.: 19/332,762

(22) Filed: Sep. 18, 2025

(30) Foreign Application Priority Data
Feb. 27, 2025 (KR) 10-2025-0025945

(51) Int. Cl. C23C 14/04

(52) U.S. Cl. CPC C23C 14/042

(57) ABSTRACT

A deposition mask includes a mask frame including an outer surface through which a first hole penetrates, an inner surface through which a second hole penetrates, and an upper surface in which a recessed area is defined, and a mask sheet on the upper surface of the mask frame. A connecting area defined in mask frame is connected to the first hole, the second hole, and the recessed area, the first hole includes a region having a decreasing diameter from the outer surface toward the connecting area, and the second hole includes a region having a decreasing diameter from the inner surface toward the connecting area.

### RELATED APPLCATION

This application claims priority to Korean Patent Application No. 10-2025-0025945 filed on February 27, 2025, and all the benefits accruing therefrom under 35 U.S.C. §119, the content of which in its entirety is herein incorporated by reference.

### BACKGROUND

### Field

An embodiment of the disclosure relates to a deposition mask, a display device manufactured using the same and an electronic device including the display device.

### Description of the Related Art

With the growing interest in information displays in recent years, research and development of display devices or electronic devices is being continuously carried out.

### SUMMARY

The problem the disclosure seeks to solve is to facilitate removal of residual cleaning fluid from a deposition mask.

The problem of the disclosure is not limited to those mentioned above, and other technical problem not mentioned will be clearly understood by those skilled in the art from the following description.

A deposition mask in an embodiment to solve the above problem includes a mask frame including an outer surface through which a first hole penetrates, an inner surface through which a second hole penetrates, and an upper surface in which a recessed area is defined, and a mask sheet on the upper surface of the mask frame. A connecting area defined in mask frame is connected to the first hole, the second hole, and the recessed area, the first hole includes a region having a decreasing diameter from the outer surface toward the connecting area, and the second hole includes a region having a decreasing diameter from the inner surface toward the connecting area.

In an embodiment, the recessed area may overlap the mask sheet.

In an embodiment, the recessed area may include a long side extending in a first direction and a short side extending in a second direction intersecting the first direction.

In an embodiment, the first hole may penetrate the outer surface in a second direction.

In an embodiment, the first hole may include a first sub-hole and a second sub-hole spaced apart in a first direction intersecting the second direction.

In an embodiment, the recessed area may overlap the first sub-hole and the second sub-hole of the first hole.

In an embodiment, the second hole may penetrate the inner surface in a second direction.

In an embodiment, the connecting area may penetrate the interior of the mask frame in a third direction.

In an embodiment, the mask frame may define an opening area surrounded by the inner surface.

In an embodiment, the mask sheet may define an opening that overlaps the opening area.

In an embodiment, the deposition mask may further include a first fixing member and a second fixing member to fix the mask frame and the mask sheet.

In an embodiment, the first fixing member may be disposed on one side of the recessed area, and the second fixing member may be disposed on another side of the recessed area.

In an embodiment, a first side portion of the connecting area may be connected to the first hole, a second side portion of the connecting area may be connected to the second hole, and an upper portion of the connecting area may be connected to the recessed area.

In an embodiment, an electronic device in an embodiment to solve the above problem may include a display device manufactured using the deposition mask.

In an embodiment, the display device may include a processor and pixels, and may display an image on the pixels under a control of the processor.

Specific details of other embodiments are included in a detailed description and drawings.

By the embodiments described above, venturi tube-shaped holes may be formed in the mask frame to facilitate the removal of cleaning fluid that remains between the mask frame and the mask sheet.

The effects of the disclosure is not limited by the above examples, and more diverse effects are included in the specification.

### BRIEF DESCRIPTION OF THE DRAWINGS

The above and other embodiments, advantages and features of this disclosure will become more apparent by describing in further detail embodiments thereof with reference to the accompanying drawings, in which:

FIG. 1 is a side view of an embodiment of a deposition apparatus.

FIG. 2 is a plan view of an embodiment of a deposition mask.

FIG. 3 is a perspective view of an embodiment of a deposition mask.

FIG. 4 is an enlarged perspective view of an embodiment of a portion of a deposition mask.

FIGS. 5 to 7 are cross-sectional views of embodiments of a deposition mask.

FIG. 8 is a block diagram illustrating an embodiment of a display device.

FIG. 9 is a block diagram illustrating an embodiment of any one of the sub-pixels of FIG. 8.

FIG. 10 is a top view illustrating an embodiment of the display panel of FIG. 8.

FIG. 11 is a block diagram of an embodiment of an electronic device.

FIG. 12 is a schematic diagram of an embodiment of an electronic device.

### DETAILED DESCRIPTION

Hereinafter, a preferred embodiment according to the disclosure may be described in detail with reference to the accompanying drawings. It should be noted that in the following description, only the parts desired to understand the operation according to the disclosure are described, and descriptions of other parts will be omitted so as not to obscure the gist of the disclosure. The disclosure is not limited to the embodiments described herein, and may be embodied in other forms. However, the embodiments described herein are provided to explain the technical idea of the disclosure in detail to a person skilled in the art to which the disclosure pertains.

Throughout the specification, when a part is “connected” to another part, this may include not only a case where the part is “directly connected” but also a case where it is “indirectly connected” with another element interposed therebetween. The terminology used herein is for the purpose of describing particular embodiments and is not intended to limit the disclosure. Throughout the specification, when it is said that a part may “include” a component, this may mean that other components may be further included, rather than excluding other components, unless otherwise specified. “At least one of X, Y, and Z”, and “at least one selected from the group consisting of X, Y and Z”, may be interpreted as one X, one Y, one Z, or any combination of two or more of X, Y or Z (e.g., XYZ, XY, YZ, ZX). Here, “and/or” may include all combinations of one or more of the corresponding configurations.

Here, terms such as first, second, and the like may be used to describe various components, but these components are not limited to these terms. These terms may be used to distinguish one component from another. Accordingly, a first component may refer to a second component without departing from what is disclosed herein.

Spatially relative terms such as “below”, “above”, and the like may be used for purposes of description, thereby describing a relationship of one element or feature to another element (s) or feature (s), as shown in the drawing figures. Spatially relative terms are intended to include different directions in use, operation, and/or manufacture, in addition to the directions depicted in the drawing figures. For example, if the device shown in the figure is flipped over, elements depicted as being “below” other elements or features may be disposed in a direction “above” the other elements or features. Thus, in an embodiment, the term “below” may include both directions above and below. In addition, the device may be directed in another direction (e.g., rotated 90 degrees or in another direction), and thus, the spatially relative terms used herein may be interpreted accordingly.

Various embodiments may be described with reference to the drawing figures schematizing ideal embodiments. Accordingly, it will be appreciated that the shapes may vary depending on, for example, tolerances and/or manufacturing techniques. Accordingly, the embodiments disclosed herein may not be construed as limited to the particular shapes shown, but may be construed as including changes in shapes that occur as a result of fabrication, for example. As such, the shapes shown in the drawings may not show actual shapes of regions of the apparatus, and the illustrated the disclosure is not limited thereto.

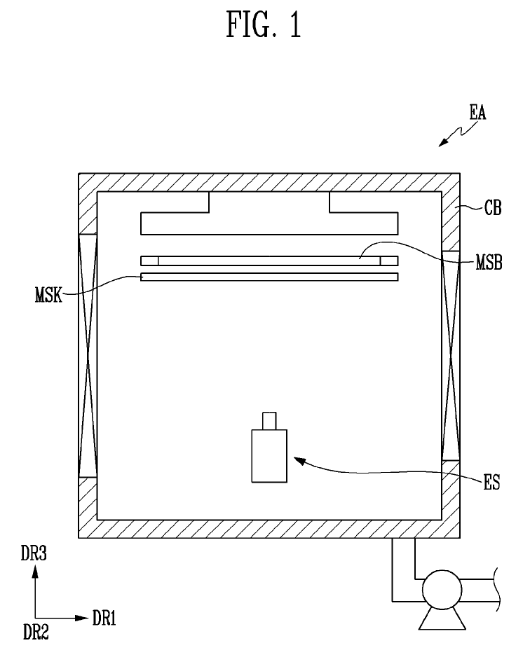

FIG. 1 is a side view of an embodiment of a deposition apparatus.

Referring to FIG. 1, a deposition apparatus EA in an embodiment may include a chamber CB, a deposition source ES, and a deposition mask MSK.

The chamber CB may have an interior space. The interior space of the chamber CB may be a workspace prepared for a deposition process. A deposition target may be housed (or placed) inside the chamber CB. In an embodiment, a mother substrate MSB that is a deposition target may be placed inside the chamber CB.

The deposition source ES may be disposed inside the chamber CB. The deposition source ES may house a deposition material and supply the deposition material to the interior space of the chamber CB. The deposition material may include a material that forms a predetermined patterned layer (e.g., a light-emitting layer) on the mother substrate MSB. The deposition source ES may apply energy (e.g., thermal energy, light energy, or vibrational energy) to the deposition material to vaporize or sublimate the deposition material. In an embodiment, the deposition source ES may include a heater therein, and may heat the deposition material inside the deposition source ES through operation of the heater, thereby melting or sublimating the deposition material, for example. The deposition source ES may be replaceable. The deposition source ES may be replaced with a new deposition source when the deposition material housed therein is exhausted.

The deposition mask MSK may be disposed between the mother substrate MSB and the deposition source ES. The deposition mask MSK may be aligned to face the deposition target. The deposition mask MSK may block the deposition material in some areas and not block the deposition material in other areas. Accordingly, the deposition material may be selectively deposited only on predetermined areas of the deposition target. The deposition mask MSK may define opening areas. The deposition material may be provided to the deposition target (or the mother substrate MSB) through the opening areas. In an embodiment, deposition may be performed simultaneously on multiple deposition targets using a single deposition mask MSK.

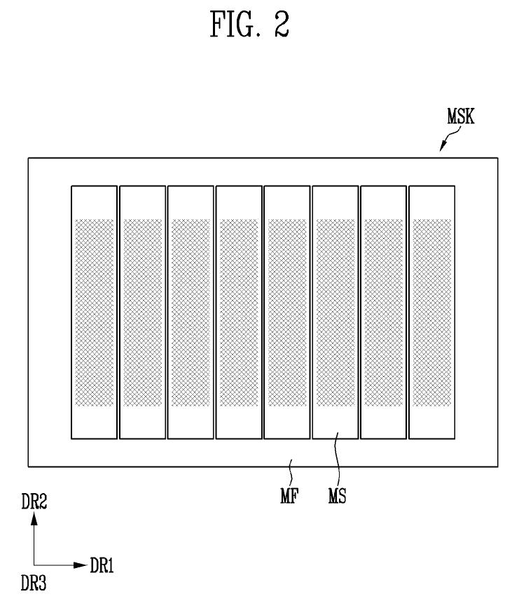

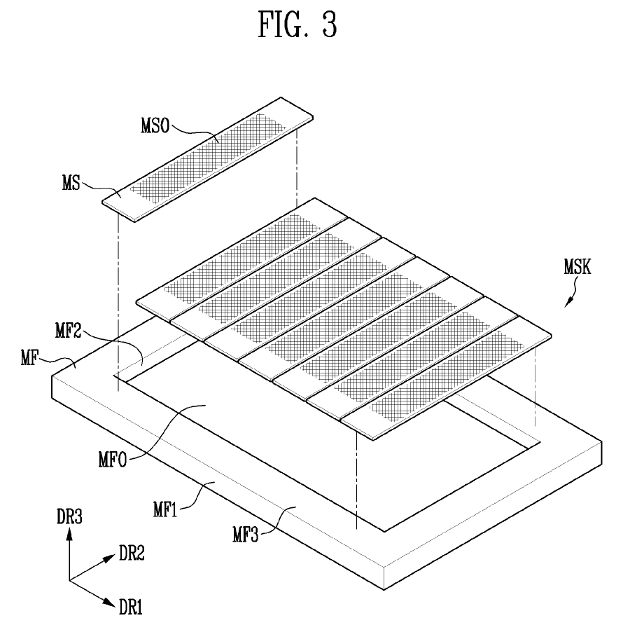

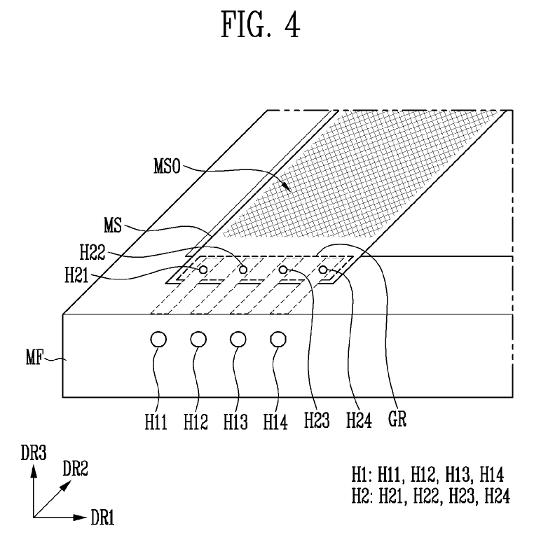

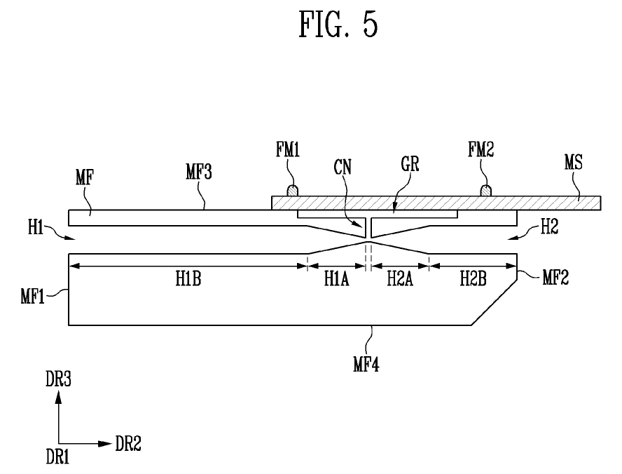

FIG. 2 is a plan view of an embodiment of a deposition mask. FIG. 3 is a perspective view of an embodiment of a deposition mask. FIG. 4 is an enlarged perspective view of an embodiment of a portion of a deposition mask. FIGS. 5 to 7 are cross-sectional views of embodiments of a deposition mask.

Referring to FIGS. 2 to 7, a deposition mask MSK may include a mask frame MF and a mask sheet MS.

The mask frame MF may define an opening area MFO. The opening area MFO may be disposed in a center of the mask frame MF. FIG. 3 illustrates an embodiment in which the mask frame MF includes a single opening area MFO, but is not necessarily limited thereto. In an embodiment, the opening areas MFO may be provided in plural.

The mask frame MF may include an outer surface MF1, an inner surface MF2, an upper surface MF3, and/or a lower surface MF4. The opening area MFO of the mask frame MF may be surrounded by the inner surface MF2. The Mask sheets MS may be disposed on the upper surface MF3 of the mask frame MF. Each of the mask sheets MS may define an opening MSO that overlaps the opening area MFO of the mask frame MF. The deposition material may be deposited on the mother substrate MSB by passing through the opening areas MFO of the mask frame MF and the opening MSO of the mask sheets MS.

The mask frame MF may include a first hole H1 penetrating the outer surface MF1. The first hole H1 may penetrate the outer surface MF1 in a second direction DR2. The first hole H1 may include first to fourth sub-holes H11 to H14. The first to fourth sub-holes H11 to H14 of the first hole H1 may be spaced apart in a first direction DR1 that intersects the second direction DR2. In In the drawing, an embodiment is illustrated in which the first hole H1 includes four sub-holes H11 to H14, but is not necessarily limited thereto, and the number of sub-holes of the first hole H1 may be varied. In an embodiment, the first hole H1 may be defined by milling, but is not necessarily limited thereto.

The mask frame MF may include a second hole H2 penetrating the inner surface MF2. The second hole H2 may penetrate the inner surface MFb in the second direction DR2. The second hole H2 may include first to fourth sub-holes H21 to H24. The first to fourth sub-holes H21 to H24 of the second hole H2 may be spaced apart in the first direction DR1. In the drawing, an embodiment is illustrated in which the second hole H2 includes four sub-holes H21 to H24, but is not necessarily limited thereto, and the number of sub-holes of the second hole H2 may be varied. In an embodiment, the second hole H2 may be defined by milling, but is not necessarily limited thereto.

The mask frame MF may include an upper surface MF3 in which a recessed area GR is defined. The recessed area GR may include a long side extending in the first direction DR1 and a short side extending in the second direction DR2. In the drawing, an embodiment is illustrated in which the recessed area GR has a quadrangular shape, e.g., rectangular shape in a plan view, but is not necessarily limited thereto, and a planar shape of the recessed area GR may be varied. In an embodiment, the recessed area GR may be defined by milling, but is not necessarily limited thereto.

In an embodiment, one recessed area GR may overlap the first to fourth sub-holes H11 to H14 of the first hole H1 and/or the first to fourth sub-holes H21 to H24 of the second hole H2, but is not necessarily limited thereto.

In an embodiment, fixing members FM1 and FM2 may be further disposed around a periphery of the recessed area GR. In an embodiment, a first fixing member FM1 may be disposed on one side of the recessed area GR and a second fixing member FM2 may be disposed on another side of the recessed area GR. The fixing members FM1 and FM2 may serve to fix or couple the mask frame MF and the mask sheet MS to each other. In an embodiment, the mask frame MF and the mask sheet MS may be fixed by welding, for example, but are not necessarily limited thereto.

The mask frame MF may include a connecting area CN connected with the first hole H1, the second hole H2, and/or the recessed area GR. A first side portion of the connecting area CN may be connected to the first hole H1, a second side portion of the connecting area CN may be connected to the second hole H2, and an upper portion of the connecting area CN may be connected to the recessed area GR.

The connecting area CN may at least partially penetrate an interior of the mask frame MF. In an embodiment, as shown in FIG. 5, the connecting area CN may at least partially penetrate the interior of the mask frame MF in a third direction DR3 that intersects (or is orthogonal to) the first direction DR1 and/or the second direction DR2, for example.

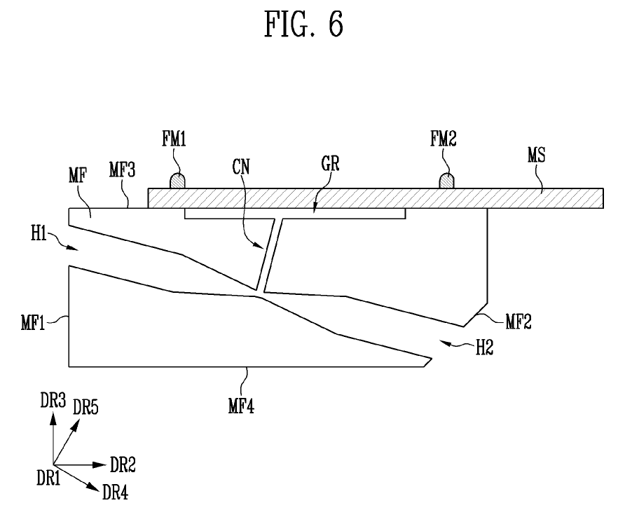

In an alternative embodiment, as shown in FIG. 6, the first hole H1 and the second hole H2 may at least partially penetrate the interior of the mask frame MF in a fourth direction DR4 that is inclined to the second direction DR2 and/or the third direction DR3, and the connecting area CN may at least partially penetrate the interior of the mask frame MF in a fifth direction DR5 that intersects (or is orthogonal to) the fourth direction DR4.

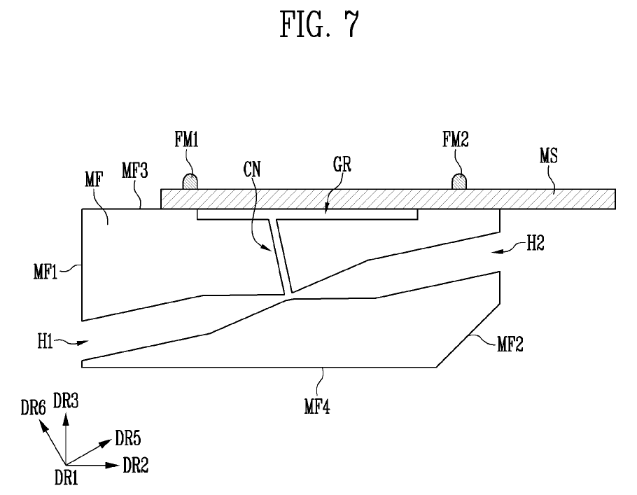

In an alternative embodiment, as shown in FIG. 7, the first hole H1 and the second hole H2 may at least partially penetrate the interior of the mask frame MF in the fifth direction DR5, and the connecting area CN may at least partially penetrate the interior of the mask frame MF in a sixth direction DR6 that intersects (or is orthogonal to) the fifth direction DR5. In an embodiment, the connecting area CN may be defined by milling, but is not necessarily limited thereto.

In an embodiment, the first hole H1, the second hole H2, and/or the connecting area CN may have a venturi tube shape. In an embodiment, the first hole H1 may include a first region H1A and a second region H1B having different diameters from each other, for example. The first region H1A of the first hole H1 may be a region in which the diameter decreases from the outer surface MF1 toward the connecting area CN. The second region H1B of the first hole H1 may be a region having a constant diameter. The diameter of the first region H1A of the first hole H1 may be smaller than the diameter of the second region H1B of the first hole H1. The first region H1A of the first hole H1 may be disposed between the second region H1B of the first hole H1 and the connecting area CN.

The second hole H2 may include a first region H2A and a second region H2B having different diameters. The first region H2A of the second hole H2 may be a region in which the diameter decreases from the inner surface MF2 toward the connecting area CN. The second region H2B of the second hole H2 may be a region having a constant diameter. The diameter of the first region H2A of the second hole H2 may be smaller than the diameter of the second region H2B of the second hole H2. The first region H2A of the second hole H2 may be disposed between the second region H2B of the second hole H2 and the connecting area CN.

The second region H1B of the first hole H1 and/or the second region H2B of the second hole H2 may serve as a passageway through which a cleaning gas is introduced or residual cleaning liquid is discharged. The first region H1A of the first hole H1 and/or the first region H2A of the second hole H2 may have characteristics where a fluid velocity increases while the pressure decreases. In an embodiment, when the cleaning gas is introduced through the second region H1B of the first hole H1, the fluid velocity may increase and the pressure may decrease as the cleaning gas passes through the first region H1A of the first hole H1. As the pressure of the cleaning gas decreases, residual cleaning liquid remaining between the mask frame MF and the mask sheet MS, e.g., in the recessed area GR, may flow into the connecting area CN and be discharged through the second region H2B of the second hole H2, thereby allowing the residual cleaning liquid to be easily removed.

In an embodiment, when the cleaning gas is introduced through the second region H2B of the second hole H2, the cleaning gas passes through the first region H2A of the second hole H2, resulting in an increase in flow velocity and a decrease in pressure. As the pressure of the cleaning gas decreases, residual cleaning liquid remaining between the mask frame MF and the mask sheet MS, e.g., in the recessed area GR, may flow into the connecting area CN and be discharged through the second region H1B of the first hole H1, thereby allowing the residual cleaning liquid to be easily removed. Accordingly, an impact of the residual cleaning liquid may be minimized, and a reliability of the display device (or an electronic device) may be improved.

Hereinafter, a display device manufactured using the deposition mask MSK described with reference to FIGS. 1 to 7, and an electronic device including the same, will be described.

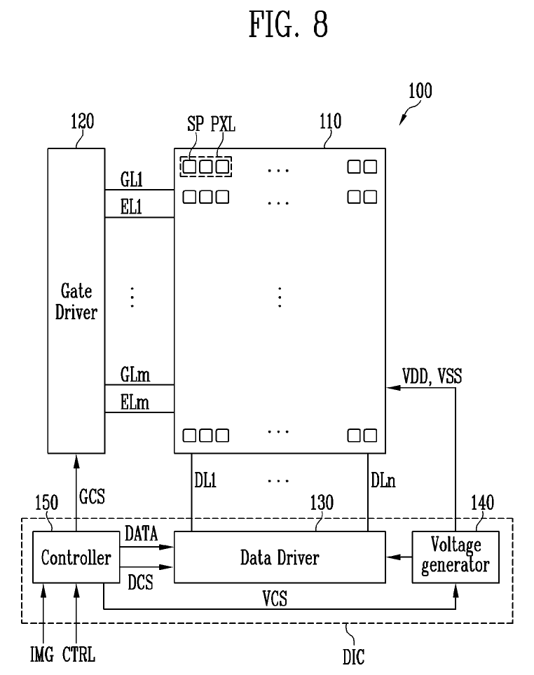

FIG. 8 is a block diagram illustrating an embodiment of a display device.

The display device 100 of FIG. 8 may be manufactured using the deposition mask MSK described above.

Referring to FIG. 8, the display device 100 may include a display panel 110, a gate driver 120, a data driver 130, a voltage generator 140, and a controller 150.

The display panel 110 may include sub-pixels SP. The sub-pixels SP may be connected to the gate driver 120 via first to m-th gate lines GL1 to GLm. The sub-pixels SP may be connected to the data driver 130 via first to n-th data lines DL1 to DLn. Here, n and m are each a natural number.

Each of the sub-pixels SP may include at least one light-emitting element configured to generate light. Accordingly, each of the sub-pixels SP may generate light of a particular color, such as red, green, blue, cyan, magenta, yellow, etc. Two or more of the sub-pixels SP may form one pixel PXL. In an embodiment, as illustrated in FIG. 8, three sub-pixels SP may constitute a single pixel PXL, for example.

The gate driver 120 may be coupled to the sub-pixels SP arranged in a row direction via the first to m-th gate lines GL1 to GLm. The gate driver 120 may output gate signals to the first to m-th gate lines GL1 to GLm in response to a gate control signal GCS. In an embodiment, the gate control signal GCS may include a start signal to indicate a start of each frame, a horizontal synchronization signal to output gate signals in synchronization with a timing of data signals being applied, or the like.

In an embodiment, first to m-th light emission control lines EL1 to ELm connected to sub-pixels SP in the row direction may be further provided. In such cases, the gate driver 120 may include a light emission control driver configured to control the first to m-th light emission control lines EL1 to ELm, and the light emission control driver may operate under a control of the controller 150.

The gate driver 120 may be disposed on one side of the display panel 110. However, the disclosure is not limited thereto. In an embodiment, the gate driver 120 may be physically and/or logically separated into two or more drivers, and such drivers may be disposed on one side of the display panel 110 and on another side of the display panel 110 opposite the one side, for example. As such, the gate drivers 120 may be disposed around the periphery of the display panel 110 in various configurations in embodiments.

The data driver 130 may be connected to the sub-pixels SP arranged in a column direction via first to n-th data lines DL1 to DLn. The data driver 130 may receive image data DATA and a data control signal DCS from the controller 150. The data driver 130 may operate in response to the data control signal DCS. In an embodiment, the data control signal DCS may include a source start pulse, a source shift clock, a source output enable signal, or the like.

Using voltages from the voltage generator 140, the data driver 130 may apply data signals having a grayscale voltage corresponding to the image data DATA to the first to n-th data lines DL1 to DLn. When a gate signal is applied to each of the first to m-th gate lines GL1 to GLm, data signals corresponding to the image data DATA may be applied to the first to n-th data lines DL1 to DLn. Accordingly, the corresponding sub-pixels SP may generate light corresponding to the data signals. Accordingly, the image may be displayed on the display panel 110.

In an embodiment, the gate driver 120 and the data driver 130 may include complementary metal-oxide semiconductor (“CMOS”) circuit elements.

The voltage generator 140 may operate in response to a voltage control signal VCS from the controller 150. The voltage generator 140 may generate voltages and provide the generated voltages to components of the display device 100. In an embodiment, the voltage generator 140 may generate the voltages by receiving an input voltage from external to the display device 100 and regulating the received voltage, for example.

The voltage generator 140 may generate a first power voltage VDD and a second power voltage VSS, and the first and second power voltages VDD and VSS may be provided to the sub-pixels SP. The first power voltage VDD may have a relatively high voltage level, and the second power voltage VSS may have a lower voltage level than the first power voltage VDD. In another embodiment, the first power voltage VDD or the second power voltage VSS may be provided by an external device to the display device 100.

In addition, the voltage generator 140 may generate various voltages. In an embodiment, the voltage generator 140 may generate an initialization voltage that is applied to the sub-pixels SP, for example. In an embodiment, in a sensing operation for sensing electrical characteristics of transistors and/or light-emitting elements of the sub-pixels SP, a predetermined reference voltage may be applied to the first to n-th data lines DL1 to DLn, and the voltage generator 140 may generate such a reference voltage, for example.

The controller 150 may control various operations of the display device 100. The controller 150 may receive input image data IMG and a control signal CTRL to control a display of the input image data IMG from an external source. In response to the control signal CTRL, the controller 150 may provide the gate control signal GCS, the data control signal DCS, and the voltage control signal VCS.

The controller 150 may convert the input image data IMG to be suitable for the display device 100 or display panel 110 to output image data DATA. In an embodiment, the controller 150 may output the image data DATA by arranging the input image data IMG to be suitable for the sub-pixels SP on a row-by-row.

Two or more components among the data driver 130, the voltage generator 140, and the controller 150 may be disposed (e.g., mounted) on a single integrated circuit. As shown in FIG. 8, the data driver 130, the voltage generator 140, and the controller 150 may be included in a driver integrated circuit DIC. In such cases, the data driver 130, the voltage generator 140, and the controller 150 may be functionally distinct components within the single driver integrated circuit DIC. In another embodiment, at least one among the data driver 130, the voltage generator 140, and the controller 150 may be provided as a component separate from the driver integrated circuit DIC.

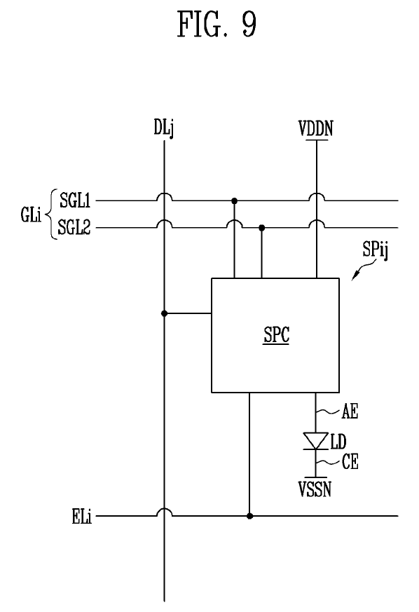

FIG. 9 is a block diagram illustrating an embodiment of any one of the subpixels of FIG. 8. In FIG. 9, a sub-pixel SPij disposed in an i-th row (where i is an integer greater than or equal to 1 and less than or equal to m) and a j-th column (where j is an integer greater than or equal to 1 and less than or equal to n) among the sub-pixels SP of FIG. 8 may be illustrated as one of the embodiments.

Referring to FIG. 9, the sub-pixel SPij may include a sub-pixel circuit SPC and a light-emitting element LD.

The light-emitting element LD may be connected between a first power voltage node VDDN and a second power voltage node VSSN. The first power voltage node VDDN may be a node that delivers the first power voltage VDD in FIG. 8, and the second power voltage node VSSN may be a node that delivers the second power voltage VSS in FIG. 8.

An anode electrode AE of the light-emitting element LD may be connected to the first power voltage node VDDN via the sub-pixel circuit SPC, and a cathode electrode CE of the light-emitting element LD may be connected to the second power voltage node VSSN. In an embodiment, the anode electrode AE of the light-emitting element LD may be connected to the first power voltage node VDDN via one or more transistors included in the sub-pixel circuit SPC, for example.

The sub-pixel circuit SPC may be connected to an i-th gate line GLi of the first to m-th gate lines GL1 to GLm of FIG. 8, an i-th emission light control line ELi of the first to m-th light emission control lines EL1 to ELm of FIG. 8, and a j data line DLj of the first to n-th data lines DL1 to DLn of FIG. 8. The sub-pixel circuit SPC may control the light-emitting element LD in response to signals received via these signal lines.

The sub-pixel circuit SPC may operate in response to a gate signal received via the i-th gate line GLi. The i-th gate line GLi may include one or more sub-gate lines. In an embodiment, the i-th gate line GLi may include first and second sub-gate lines SGL1 and SGL2. The sub-pixel circuit SPC may operate in response to gate signals received via the first and second sub-gate lines SGL1 and SGL2. As such, in case that the i-th gate line GLi includes two or more sub gate lines, the sub-pixel circuit SPC may operate in response to gate signals received through those sub-gate lines.

The sub-pixel circuit SPC may operate in response to an emission control signal received via the i-th light emission control line ELi. In an embodiment, the i-th light emission control line ELi may include one or more sub-emission control lines. In case that the first light emission control line ELi includes two or more sub-emission control lines, the sub-pixel circuit SPC may operate in response to emission control signals received through those sub-emission control lines.

The sub-pixel circuit SPC may receive a data signal via the j-th data line DLj. The sub-pixel circuit SPC may store a voltage corresponding to the data signal in response to at least one of the gate signals received via the first and second sub-gate lines SGL1 and SGL2. In response to the emission control signal received via the i-th light emission control line ELi, the sub-pixel circuit SPC may adjust the current flowing from the first power voltage node VDDN to the second power voltage node VSSN through the light-emitting element LD according to the stored voltage. Accordingly, the light-emitting element LD may generate light of a luminance corresponding to the data signal.

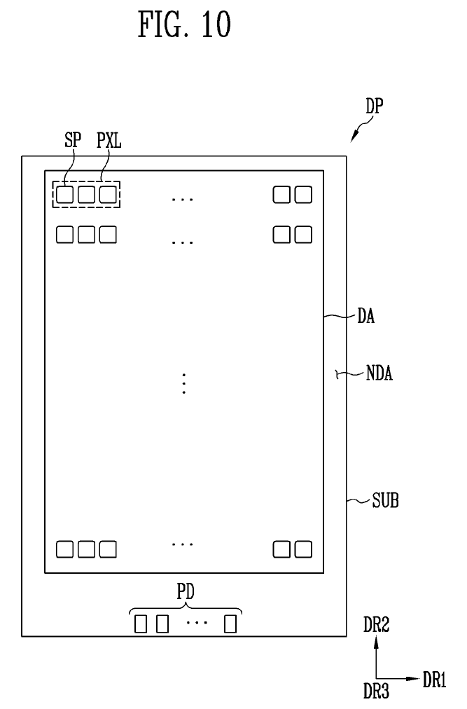

FIG. 10 is a top view illustrating an embodiment of the display panel of FIG. 8.

Referring to FIG. 10, an embodiment of the display panel DP may include a display area DA and a non-display area NDA. The display panel DP may display an image through the display area DA. The non-display area NDA may be disposed around the display area DA.

The display panel DP may include a substrate SUB, sub-pixels SP, and pads PD.

The sub-pixels SP may be disposed in the display area DA on the substrate SUB. The sub-pixels SP may be arranged in a matrix form along a first direction DR1 and a second direction DR2 intersecting the first direction DR1. However, the disclosure is not limited thereto. In an embodiment, the sub-pixels SP may be arranged in a zigzag shape along the first direction DR1 and the second direction DR2, for example. In an embodiment, the sub-pixels SP may be arranged in a PENTILE^{TM} form, for example. The first direction DR1 may be a row direction, and the second direction DR2 may be a column direction. Two or more sub-pixels of the sub-pixels SP may constitute one pixel PXL.

In the non-display area NDA on the substrate SUB, components for controlling the sub-pixels SP may be located. In an embodiment, wiring associated with the sub pixels SP, such as the first to m-th gate lines GL1 to GLm and the first to n-th data lines DL1 to DLn in FIG. 8, may be arranged in the non-display area NDA, for example.

At least one among the gate driver 120, the data driver 130, the voltage generator 140, and the controller 150 of FIG. 8 may be integrated in the non-display area NDA of the display panel DP. In an embodiment, the gate driver 120 of FIG. 8 may be disposed (e.g., mounted) on the display panel DP and disposed in the non-display area NDA. In another embodiment, the gate driver 120 may be implemented as an integrated circuit separate from the display panel DP.

The pads PD may be disposed in the non-display area NDA on the substrate SUB. The pads PD may be electrically connected to the sub-pixels SP through wirings. In an embodiment, the pads PD may be connected to the sub-pixels SP via first to n-th data lines DL1 to DLn, for example.

The pads PD may interface the display panel DP to other components of the display device 100. In an embodiment, voltages and signals desired for operation of the components included in the display panel DP may be provided from a driver integrated circuit DIC through the pads PD. In an embodiment, the first to n-th data lines DL1 to DLn may be connected to the driver integrated circuit DIC via the pads PD, for example. In an embodiment, the first and second power voltages VDD and VSS may be received from the driver integrated circuit DIC via the pads PD, for example. In an embodiment, in case that the gate driver 120 is disposed (e.g., mounted) on the display panel DP, a gate control signal GCS may be transmitted to the gate driver 120 via the pads PD from the driver integrated circuit DIC, for example.

In an embodiment, a circuit board may be electrically connected to the pads PD using a conductive adhesive member such as an anisotropic conductive film. In this case, the circuit board may be a flexible circuit board or a flexible film having a flexible material. The driver integrated circuit DIC may be disposed (e.g., mounted) on the circuit board and electrically connected to the pads PD.

In an embodiment, the display area DA may have various shapes. The display area DA may have the shape of a closed loop including straight and/or curved sides. In an embodiment, the display area DA may have shapes such as a polygon, a circle, a semicircle, an ellipse, or the like, for example.

In an embodiment, the display panel DP may have a flat display surface. In another embodiment, the display panel DP may have an at least partially rounded display surface. In an embodiment, the display panel DP may be bendable, foldable, or rollable. In such cases, the display panel DP and/or the substrate SUB may include materials having a flexible property.

The display device 100 in an embodiment may be applied to various electronic devices. The electronic device in an embodiment includes the display device 100 described above, and may further include a module or device having an additional function other than the display device 100.

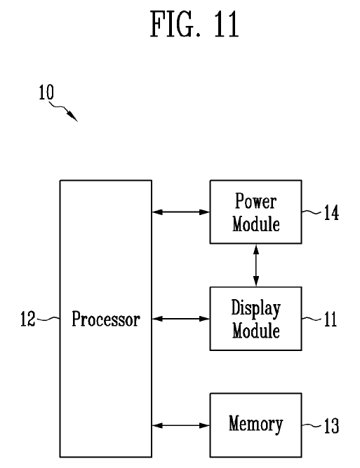

FIG. 11 is a block diagram of an embodiment of an electronic device.

Referring to FIG. 11, the electronic device 10 in an embodiment may include a display module 11, a processor 12, a memory 13, and a power module 14.

The processor 12 may include at least one of a central processing unit (“CPU”), an application processor (“AP”), a graphics processing unit (“GPU”), a communication processor (“CP”), an image signal processor (“ISP”), and a controller.

The memory 13 may store data information desired for the operation of the processor 12 or the display module 11. When the processor 12 executes an application stored in the memory 13, an image data signal and/or an input control signal are transmitted to the display module 11, and the display module 11 may process the received signal and output image information through a display screen.

The power module 14 may include a power supply module such as a power adapter, a battery device, or the like, and a power conversion module that converts power supplied by the power supply module to generate power desired for operation of the electronic device 10.

At least one of the above-described components of the electronic device 10 may be included in the display device 100 according to the above-described embodiments. In addition, some parts of individual modules functionally included in one module may be included in the display device 100, and other parts may be provided separately from the display device 100. In an embodiment, the display device 100 may include the display module 11, and the processor 12, the memory 13, and the power module 14 may be provided in the form of other devices in the electronic device 10 other than the display device 100, for example.

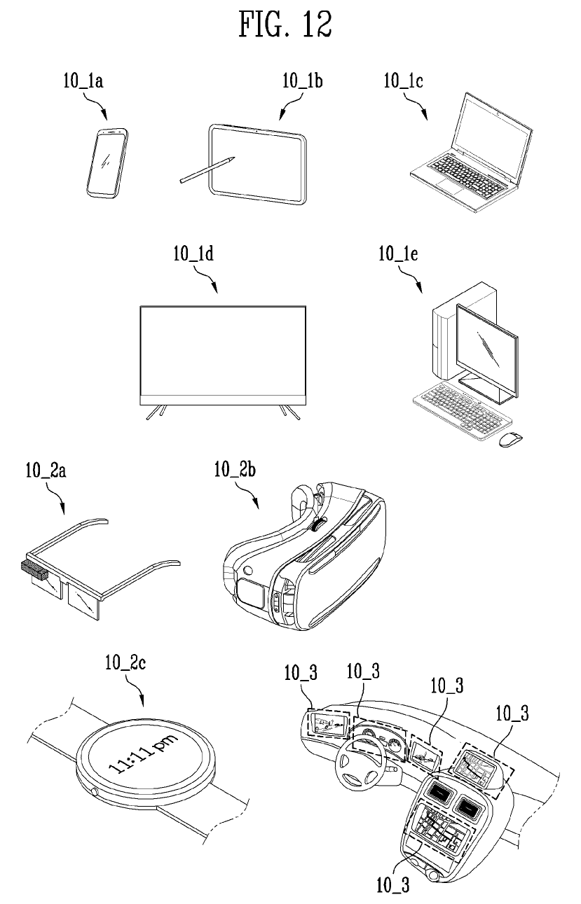

FIG. 12 is a schematic diagram of an embodiment of an electronic device.

Referring to FIG. 12, various electronic devices 10 to which a display device 100 in embodiments is applied may include not only an electronic device for displaying an image such as a smartphone 10_1a, a tablet PC 10_1b, a laptop 10_1c, a television (“TV”) 10_1d, and a desk monitor 10_1e, but also a wearable electronic device including a display module such as smart glasses 10_2a, a head mounted display 10_2b, and a smart watch 10_2c, an automotive electronic device 10_3 including a display module, such as a Center Information Display (“CID”) disposed on an instrument panel, a center fascia, and a dashboard of a vehicle, a room mirror display, or the like.

Although illustrative embodiments have been described herein, other embodiments and variations may be derived from the above description. Accordingly, the spirit of the disclosure is not limited to these embodiments, but extends to the claims, various obvious modifications, and equivalents set forth below.

What is claimed is:

1. A deposition mask comprising:
a mask frame including:
an outer surface through which a first hole penetrates;
an inner surface through which a second hole penetrates; and
an upper surface in which a recessed area is defined; and
a mask sheet on the upper surface of the mask frame,
wherein a connecting area defined in mask frame is connected to the first hole, the second hole, and the recessed area,
the first hole includes a region having a decreasing diameter from the outer surface toward the connecting area, and
wherein the second hole includes a region having a decreasing diameter from the inner surface toward the connecting area.

2. The deposition mask of claim 1, wherein the recessed area overlaps the mask sheet.

3. The deposition mask of claim 1, wherein the recessed area includes a long side extending in a first direction and a short side extending in a second direction intersecting the first direction.

4. The deposition mask of claim 1, wherein the first hole penetrates the outer surface in a second direction.

5. The deposition mask of claim 4, wherein the first hole includes a first sub-hole and a second sub-hole spaced apart in a first direction intersecting the second direction.

6. The deposition mask of claim 5, wherein the recessed area overlaps the first sub-hole and the second sub-hole of the first hole.

7. The deposition mask of claim 1, wherein the second hole penetrates the inner surface in a second direction.

8. The deposition mask of claim 1, wherein the connecting area penetrates the interior of the mask frame in a third direction.

9. The deposition mask of claim 1, wherein the mask frame defines an opening area surrounded by the inner surface.

10. The deposition mask of claim 9, wherein the mask sheet defines an opening which overlaps the opening area.

11. The deposition mask of claim 1, further comprising:
a first fixing member and a second fixing member to fix the mask frame and the mask sheet.

12. The deposition mask of claim 11, wherein the first fixing member is disposed on one side of the recessed area, and the second fixing member is disposed on another side of the recessed area.

13. The deposition mask of claim 1, wherein a first side portion of the connecting area is connected to the first hole,
wherein a second side portion of the connecting area is connected to the second hole, and
wherein an upper portion of the connecting area is connected to the recessed area.

14. An electronic device comprising a display device manufactured using the deposition mask of claim 1.

15. The electronic device of claim 14, wherein the display device includes a processor and pixels, and displays an image on the pixels under a control of the processor.
